(19) United States
(12) Patent Application Publication
(10) Pub. No.: US 2025/0107225 A1
(43) Pub. Date: Mar. 27, 2025

(54) METHOD FOR IMPROVING PERFORMANCE OF MOS DEVICE

(71) Applicant: Shanghai Huali Integrated Circuit Corporation, Shanghai (CN)

(72) Inventor: Huiyun JIANG, Shanghai (CN)

(73) Assignee: Shanghai Huali Integrated Circuit Corporation, Shanghai (CN)

(21) Appl. No.: 18/783,249

(22) Filed: Jul. 24, 2024

(30) Foreign Application Priority Data
Sep. 26, 2023 (CN) 202311254232.5

(51) Int. Cl. H01L 27/092; H01L 21/28; H01L 21/8238; H01L 29/49

(52) U.S. Cl. CPC H10D 84/85; H01L 21/28088; H10D 64/667; H10D 84/0177; H10D 84/038

(57) ABSTRACT

The present disclosure provides a method for improving performance of a MOS device, including: providing a work function layer; forming a barrier layer on the work function layer; forming a metal layer on the barrier layer, wherein the material of the metal layer is tungsten, and the thickness of the metal layer is 3000 Å; and etching the metal layer, the barrier layer, and the work function layer to form a gate structure. The present disclosure replaces an Al gate material in the conventional 22 nm process with tungsten, and replaces a Ti adhesive layer and a TiN barrier layer below an Al gate with a TiN barrier layer of 25 Å. The present disclosure greatly reduces a gate resistance of the MOS device and enhances a tensile stress of a channel, thereby improving the performance of the NMOS device.

### CROSS-REFERENCE TO RELATED APPLICATIONS

This application claims priority to Chinese patent application No. 202311254232.5, filed on Sep. 26, 2023, the disclosure of which is incorporated herein by reference in its entirety.

### TECHNICAL FIELD

The present disclosure relates to the technical field of semiconductors, and in particular to a method for improving performance of a MOS device.

### BACKGROUND

The gate material of the current 22 nm technology is Al. Al has a serious diffusion problem that requires a barrier layer to prevent diffusion, leading to a large gate resistance. Moreover, diffused Al affects a work function (WF) of a PMOS, slowing down the speed of a PMOS device.

The current 22 nm technology relies on SiGe to improve the performance of the PMOS device, which is highly effective, while an NMOS can only rely on a contact etch stop layer (CESL) to improve the device performance. Accordingly, it is necessary to further improve the performance of the NMOS device.

### BRIEF SUMMARY

The present disclosure provides a method for improving performance of a MOS device, at least including:
step I, providing a work function layer;
step II, forming a barrier layer on the work function layer;
step III, forming a metal layer on the barrier layer, wherein the material of the metal layer is tungsten, and the thickness of the metal layer is 3000 Å; and
step IV, etching the metal layer, the barrier layer, and the work function layer to form a gate structure.

In some examples, the work function layer in step I is a work function layer for forming a gate structure of an NMOS device.

In some examples, the work function layer in step I is TiAl, and the thickness of the work function layer is 70 Å.

In some examples, the barrier layer in step II is a TiN layer.

In some examples, the thickness of the barrier layer in step II is 25 Å.

In some examples, the metal layer in step III is used for forming a metal gate in the gate structure of the MOS device.

In some examples, the thickness of the metal layer in step III is 3000 Å.

In some examples, the method is applicable to a process for a MOS gate at the 22 nm technology node.

In some examples, the method is used to reduce a gate resistance of the MOS device and enhance a tensile stress of a channel.

As described above, the method for improving performance of a MOS device of the present disclosure has the following beneficial effects: the present disclosure replaces an Al gate material in the conventional 22 nm process with tungsten, and replaces a Ti adhesive layer and a TiN barrier layer below an Al gate with a TiN barrier layer of 25 Å. The present disclosure greatly reduces a gate resistance of the MOS device and enhances a tensile stress of a channel, thereby improving the performance of the NMOS device.

### BRIEF DESCRIPTION OF THE DRAWINGS

FIG. 1 illustrates a schematic diagram of a gate structure of a MOS device in the present disclosure; and

FIG. 2 illustrates a flowchart of a method for improving performance of a MOS device in the present disclosure.

### DETAILED DESCRIPTION OF THE DISCLOSURE

The embodiments of the present disclosure are described below using specific examples, and those skilled in the art could readily understand other advantages and effects of the present disclosure from the contents disclosed in the description. The present disclosure can also be implemented or applied using other different specific implementations, and various details in the description can also be modified or changed based on different viewpoints and disclosures without departing from the spirit of the present disclosure.

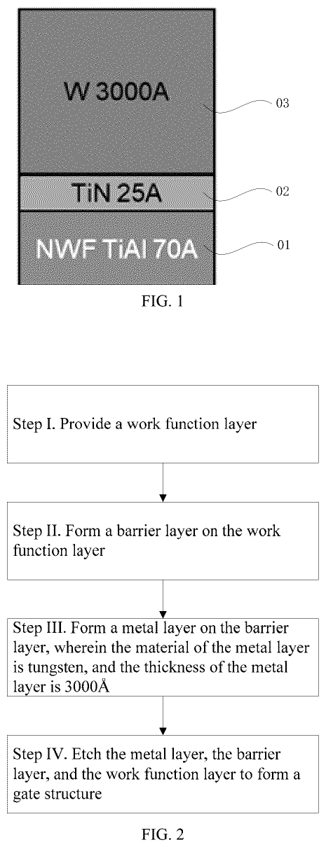

References are made to FIGS. 1 to 2. It should be noted that the drawings provided in the embodiments are only used to illustrate the basic concept of the present disclosure in a schematic way, so the drawings only show the components related to the present disclosure rather than being drawn according to the number, shape, and size of the components in actual implementations. The type, number, and proportion of various components can be changed randomly in the actual implementations, and the layout of the components may be more complicated.

The present disclosure provides a method for improving performance of a MOS device. Referring to FIG. 2, FIG. 2 illustrates a flowchart of the method for improving performance of a MOS device in the present disclosure. The method at least includes the following steps.

Step I. A work function layer is provided.

Furthermore, in this embodiment of the present disclosure, the work function layer in step I is a work function layer for forming a gate structure of an NMOS device. Furthermore, in this embodiment of the present disclosure, the work function layer in step I is TiAl, and the thickness of the work function layer is 70 Å.

Referring to FIG. 1, FIG. 1 illustrates a schematic diagram of a gate structure of a MOS device in the present disclosure. In step I, the work function layer 01 is provided. In this embodiment, the work function layer 01 is used for forming the gate structure of the NMOS device. In other embodiments, the work function layer may be also used for forming a gate structure of a PMOS device. In this embodiment, the work function layer 01 is TiAl, and the thickness of the work function layer 01 is 70 Å.

Step II. A barrier layer is formed on the work function layer. Referring to FIG. 1, in step II, the barrier layer 02 is formed on the work function layer 01. Furthermore, in this embodiment of the present disclosure, the barrier layer 02 in step II is a TiN layer. In this embodiment, the thickness of the barrier layer 02 in step II is 25 Å.

Step III. A metal layer is formed on the barrier layer, wherein the material of the metal layer is tungsten, and the thickness of the metal layer is 3000 Å.

Furthermore, in this embodiment of the present disclosure, the metal layer in step III is used for forming a metal gate in the gate structure of the MOS device.

Furthermore, in this embodiment of the present disclosure, the thickness of the metal layer in step III is 3000 Å.

Referring to FIG. 1, in step III, the metal layer 03 is formed on the barrier layer 02, wherein the material of the metal layer 03 is tungsten, and the thickness of the metal layer 03 is 3000 Å. In this embodiment, the metal layer in step III is used for forming the metal gate in the gate structure of the MOS device, and the thickness of the metal layer is 3000 Å. In other embodiments, the metal layer may be also used for forming a metal gate in the gate structure of the PMOS device.

Step IV. The metal layer, the barrier layer, and the work function layer are etched to form a gate structure.

Furthermore, in this embodiment of the present disclosure, the method is applicable to a process for a MOS gate at the 22 nm technology node.

Furthermore, in this embodiment of the present disclosure, the method is used to reduce a gate resistance of the MOS device and enhance a tensile stress of a channel.

FIG. 1 is a schematic structural diagram of the gate structure formed by etching the metal layer, the barrier layer, and the work function layer. In step IV, the metal layer, the barrier layer, and the work function layer formed in step I to step III are etched to form the gate structure as shown in FIG. 1.

The present disclosure replaces an Al gate material with a W gate material, and replaces a Ti adhesive layer of 50 Å and a TiN barrier layer of 50 Å below an Al gate with a TiN barrier layer of 25 Å, greatly reducing a gate resistance and enhancing a tensile stress of a channel, thereby improving the performance of the NMOS device.

In present disclosure, after the replacement with a W metal gate, an NMOS gate resistance is reduced by 67%, and a PMOS gate resistance is reduced by 33%. The performance of the NMOS device is improved by 8%, and the performance of the PMOS device remains unchanged.

To sum up, the present disclosure replaces an Al gate material in the conventional 22 nm process with tungsten, and replaces a Ti adhesive layer and a TiN barrier layer below an Al gate with a TiN barrier layer of 25 Å. The present disclosure greatly reduces a gate resistance of the MOS device and enhances a tensile stress of a channel, thereby improving the performance of the NMOS device. Therefore, the present disclosure effectively overcomes various defects in the prior art and has high industrial utilization value.

The above embodiments merely illustrate the principle and effect of the present disclosure, rather than limiting the present disclosure. Any person skilled in the art can modify or change the above embodiments without departing from the spirit and scope of the present disclosure. Therefore, all equivalent modifications or changes made by those with ordinary knowledge in the art without departing from the spirit and technical idea disclosed in the present disclosure shall still be covered by the claims of the present disclosure.

What is claimed is:

1. A method for improving performance of a MOS device, at least comprising:
step I, providing a work function layer;
step II, forming a barrier layer on the work function layer;
step III, forming a metal layer on the barrier layer, wherein the material of the metal layer is tungsten, and the thickness of the metal layer is 3000 Å; and
step IV, etching the metal layer, the barrier layer, and the work function layer to form a gate structure.

2. The method for improving performance of a MOS device according to claim 1, wherein the work function layer in step I is a work function layer for forming a gate structure of an NMOS device.

3. The method for improving performance of a MOS device according to claim 2, wherein the work function layer in step I is TiAl, and the thickness of the work function layer is 70 Å.

4. The method for improving performance of a MOS device according to claim 1, wherein the barrier layer in step II is a TiN layer.

5. The method for improving performance of a MOS device according to claim 4, wherein the thickness of the barrier layer in step II is 25 Å.

6. The method for improving performance of a MOS device according to claim 1, wherein the metal layer in step III is used for forming a metal gate in the gate structure of the MOS device.

7. The method for improving performance of a MOS device according to claim 6, wherein the thickness of the metal layer in step III is 3000 Å.

8. The method for improving performance of a MOS device according to claim 1, wherein the method is applicable to a process for a MOS gate at the 22 nm technology node.

9. The method for improving performance of a MOS device according to claim 1, wherein the method is used to reduce a gate resistance of the MOS device and enhance a tensile stress of a channel.
